(19) United States
(12) Patent Application Publication
(10) Pub. No.: US 2025/0122610 A1
(43) Pub. Date: Apr. 17, 2025

(54) Method and system for filling a gap

(71) Applicant: ASM IP Holding B.V., Almere (NL)

(72) Inventors: René Henricus Jozef Vervuurt, Leuven (BE); Timothee Blanquart, Oud-Heverlee (BE); Ranjit Borude, Tokyo (JP); Imane Abdellaoui, Leuven (BE); Viljami Pore, Helsinki (FI); Ikhlas Rahmat, Leuven Vlaams-Brabant (BE)

(21) Appl. No.: 18/914,403

(22) Filed: Oct. 14, 2024

Related U.S. Application Data
(60) Provisional application No. 63/544,458, filed on Oct. 17, 2023.

(51) Int. Cl. C23C 16/04; C23C 16/34; C23C 16/40

(52) U.S. Cl. CPC C23C 16/045; C23C 16/345; C23C 16/401

(57) ABSTRACT

Disclosed are methods and systems for filing a gap. An exemplary method comprises providing a substrate in a reaction chamber. The substrate comprises at least one gap. The method further comprises depositing a layer into the gap. The layer has a first volume. Finally, the method further comprises converting the layer into a converted layer. The converted layer has a second volume. The second volume is greater than the first volume. The methods and systems are useful, for example, in the field of integrated circuit manufacture.

### CROSS-REFERENCE TO RELATED APPLICATIONS

This application claims priority to and the benefit of U.S. Provisional Application No. 63/544,458, filed Oct. 17, 2023, the entirety of which is incorporated by reference herein.

### FIELD OF INVENTION

The present disclosure generally relates to the field of semiconductor processing methods and systems, and to the field integrated circuit manufacture. In particular, methods and systems suitable for filling a gap are disclosed.

### BACKGROUND OF THE DISCLOSURE

The scaling of semiconductor devices, such as, for example, logic devices and memory devices, has led to significant improvements in speed and density of integrated circuits. However, conventional device scaling techniques face significant challenges for future technology nodes.

For example, one challenge has been finding suitable ways of filling gaps such as recesses, trenches, vias and the like with a material without formation of any gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of filling a gap, to structures and devices formed using such methods, and to apparatus for preforming the methods and/or for forming the structures and/or devices. The layers may be used in a variety of applications. For example, they may be used in the field of integrated circuit manufacture.

Thus, described herein is a method for filling a gap. The method comprises providing a substrate in a reaction chamber. The substrate comprises at least one gap. The method further comprises depositing a layer into the gap. The layer has a first volume. Finally, the method further comprises converting the layer into a converted layer in the gap. The converted layer has a second volume. The second volume is greater than the first volume.

Further described herein is a system. The system comprises a reaction chamber. The system further comprises a first precursor gas source. The first precursor gas source comprises a first precursor. The system further comprises a second precursor gas source. The second precursor gas source comprises a second precursor. The system further comprises a controller. The controller is configured to control gas flow into the reaction chamber to form a converted layer in a gap of a substrate by a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein.

FIG. 2 illustrates an embodiment of a method as disclosed herein.

FIG. 3 illustrates the operation of an embodiment of a method as described herein.

FIG. 4 shows another embodiment of a system as described herein in a stylized way.

FIG. 5 shows a stylized representation of a substrate comprising a gap.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film. The term “reactant” can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include at least one of bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or can include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”. A method as described herein can comprise depositing a layer by means of a cyclic deposition process. The term “cyclic deposition process” or “cyclical deposition process” can refer to a sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a CVD component.

A method as described herein can comprise depositing a layer by an atomic layer deposition process. The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), thereby forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g., using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element that may be incorporated during a deposition process as described herein.

The term “reactant” can refer to a gas or a material that can become gaseous and that can react with a precursor.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

In this disclosure, any defined meanings do not necessarily exclude ordinary and customary meanings, in some embodiments.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

Described herein is a method of filling a gap. The method comprises providing a substrate that comprises a gap to a reaction chamber. A monocrystalline silicon wafer may be a suitable substrate. Other substrates may be suitable, e.g., monocrystalline germanium wafers, gallium arsenide wafers, quartz, sapphire, glass, steel, aluminum, silicon-on-insulator substrates, plastics, etc.

The method further comprises depositing a layer into the gap. The layer has a first volume. Finally, the method further comprises converting the layer into a converted layer. The converted layer has a second volume. The second volume is greater than the first volume.

The presently disclosed method describes an expansion based-gap fill process, which allows seam-free or void-free gap fill.

In some embodiments, the method further comprises a plasma trim before converting the layer into a converted layer. In the plasma trim step, a hydrogen plasma is formed into the reaction chamber, which trims the upper edges of the layer to form a V-shape. This enables the conversion elements to reach all the way to the bottom of the gap and thus fully convert the layer into the converted layer. The V-shape also prevents pinch-off, which means that the gap would be closed at the top leaving a void into the mid and bottom parts of the gap. The pinch-off effect would also complicate the transfer of the conversion elements to all parts of the layer in the gap. In some embodiments, the plasma trim time is the same for each super cycle. In some embodiments, the plasma trim time is decreased in each super cycle.

In some embodiments, the method further comprises depositing a liner layer before depositing a liner layer into the gap. The liner acts as a protective liner to prevent damage to the underlying substrate. Another task of the liner is that, as it already partially fills the gap, there is need for less deposition of a layer in the gap and thus converting that layer into the conversion layer. Therefore, it might increase the throughput. In some embodiments, the liner comprises silicon oxide. In some embodiments, the liner is a conformal atomic layer deposition liner. In some embodiments, the liner is an inhibition atomic layer deposition liner. The inhibition ALD liner allows a tapered deposition shape which may reduce the pinch-off effect.

In some embodiments, the converting step is performed by an oxidizing treatment. In some embodiments, the oxidizing treatment comprises a treatment selected from at least one of ozone, hydrogen peroxide, oxygen plasma, oxygen radicals, vacuum ultraviolet oxygen and steam.

In some embodiments, the converting step is performed by a nitriding treatment. In some embodiments, the nitriding treatment comprises a treatment selected from at least one of ammonia, ammonia plasma, hydrazine, hydrazine plasma, nitrogen/hydrogen plasma, nitrogen plasma, or nitrogen radicals.

In some embodiments, the liner layer comprises at least one material selected from the group consisting of silicon oxide, silicon, silicon carbide, and silicon nitride.

In some embodiments, the layer comprises silicon or silicon nitride.

In some embodiments, the converted layer comprises silicon oxide.

In some embodiments, the second precursor comprises a silane group. In some embodiments, the silane group is selected form the group consisting of tetrasilane, neopentasilane, silane, disilane trisilane, diiodosilane, cyclohexasilane and cyclopentasilane.

In some embodiments, the plasma trim is performed using a plasma gas comprising hydrogen, argon, helium or a mixture thereof.

In some embodiments, the liner comprises silicon oxide.

The materials formed according to the present methods can be advantageously used in the field of integrated circuit manufacture.

Exemplary gaps include recesses, contact holes, vias, trenches, and the like. In some embodiments, the gap has a width of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a depth of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

A layer as described herein can suitably be deposited using a deposition technique that yields conformal layers, such as atomic layer deposition (ALD) or another cyclical deposition process. Alternatively, a layer as described herein can be deposited using a deposition technique that yields non-conformal layers, i.e. non-uniform layers, such as layers that have a higher thickness on a flat surface of a substrate, than inside a gap or trench; or layers that have a higher thickness inside a gap or trench than on a flat surface of a substrate. Examples of techniques that can yield non-conformal layers are chemical vapor deposition and plasma-enhanced chemical vapor deposition.

Depositing a layer as described herein may comprise executing a cyclical deposition process. The cyclical deposition process can include cyclical CVD, ALD, or a hybrid cyclical CVD/ALD process or plasma-enhanced ALD/CVD process. For example, in some embodiments, the growth rate of a particular ALD process may be low compared to a CVD process. One approach to increase the growth rate may be that of operating at a higher deposition temperature than that typically employed in an ALD process, resulting in some portion of a chemical vapor deposition process, i.e., of at least one of non-self-limiting surface and gas phase reactions, but still taking advantage of the sequential introduction of reactants. Such a process may be referred to as cyclical CVD. In some embodiments, a cyclical CVD process may comprise the introduction of two or more precursors or reactants into the reaction chamber, wherein there may be a time period of overlap between the two or more precursors or reactants in the reaction chamber resulting in both an ALD component of the deposition and a CVD component of the deposition. This is referred to as a hybrid process. In accordance with further examples, a cyclical deposition process may comprise a continuous flow of one reactant or precursor and periodic pulsing of a second reactant or precursor into the reaction chamber.

In some embodiments, the liner layer and the layer are conformally deposited on the substrate. In other words, liner layer and/or the layer can have a thickness which is constant over the surface of the substrate, including in gaps, recesses, and the like, e.g. within a margin of error of 50%, 20%, 10%, 5%, 2%, 1%, 0.5%, or 0.1%.

In some embodiments, the liner layer and/or the layer is deposited by means of a deposition method that yields a growth rate at a distal surface of a gap that is higher than a growth rate at a proximal surface of the gap. In some embodiments, the growth rate at the distal surface of the gap is from at least 200% to at most 500%, or from at least 100% to at most 200%, or from at least 50% to at most 100%, or from at least 20% to at most 50%, or from at least 10% to at most 20%, or from at least 5% to at most 10%, or from at least 2% to at most 5%, or from at least 1% to at most 2% higher than the growth rate at the proximal surface of the gap.

In some embodiments, the substrate is maintained at a temperature of at least −25° C. to at most 400° C., or at a temperature of at least 0° C. to at most 200° C., or at a temperature of at least 25° C. to at most 150° C., or at a temperature of at least 50° C. to at most 100° C. while exposing the substrate to the active species.

In some embodiments, the liner layer is deposited at a substrate temperature of less than 800° C., or of at least 50° C. to at most 500° C., or of at least 100° C. to at most 300° C. In some embodiments, the liner layer is deposited at a temperature of at least −25° C. to at most 300° C., or at a temperature of at least 0° C. to at most 250° C., or at a temperature of at least 25° C. to at most 200° C., or at a temperature of at least 50° C. to at most 150° C., or at a temperature of at least 75° C. to at most 125° C.

In some embodiments, the layer is deposited at a substrate temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C.

In some embodiments, the presently described methods are carried out at a pressure of less than 760 Torr or of at least 0.2 Torr to at most 760 Torr, of at least 1 Torr to at most 100 Torr, or of at least 1 Torr to at most 10 Torr. In some embodiments, the layers are deposited at a pressure of at most 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at most 10⁻² Torr, or at a pressure of at most 10⁻³ Torr, or at a pressure of at most 10⁻⁴ Torr, or at a pressure of at most 10⁻⁵ Torr, or at a pressure of at least 0.1 Torr to at most 10 Torr, or at a pressure of at least 0.2 Torr to at most 5 Torr, or at a pressure of at least 0.5 Torr to at most 2.0 Torr.

In some embodiments, the first precursor is pulsed into the reaction chamber for a duration of at least 0.1 s to at most 1000 s, or of at least 0.2 s to at most 500 s, or of at least 0.5 s to at most 200 s, or of at least 1.0 s to at most 100 s, or of at least 2 s to at most 50 s, or of at least 5 s to at most 20 s.

In some embodiments, a method as described herein comprises a plurality of super cycles. For example, a method as described herein can comprise from at least 2 to at most 5, or from at least 5 to at most 10, or from at least 10 to at most 20, or from at least 20 to at most 50, or from at least 50 to at most 100 super cycles. A super cycle comprises depositing a layer into the gap; performing an optional plasma trim; and converting the layer into a converted layer.

The total number of super cycles comprised in a method as described herein depends, inter alia, on the total layer thickness that is desired. In some embodiments, the method comprises from at least 1 super cycle to at most 100 super cycles, or from at least 2 super cycles to at most 80 super cycles, or from at least 3 super cycles to at most 70 super cycles, or from at least 4 super cycles to at most 60 super cycles, or from at least 5 super cycles to at most 50 super cycles, or from at least 10 super cycles to at most 40 super cycles, or from at least 20 super cycles to at most 30 super cycles. In some embodiments, the method comprises at most 100 super cycles, or at most 90 super cycles, or at most 80 super cycles, or at most 70 super cycles, or at most 60 super cycles, or at most 50 super cycles, or at most 40 super cycles, or at most 30 super cycles, or at most 20 super cycles, or at most 10 super cycles, or at most 5 super cycles, or at most 4 super cycles, or at most 3 super cycles, or at most 2 super cycles, or a single super cycle.

Further described herein is a system that comprises a reaction chamber, a first precursor gas source, a second precursor gas source, and a controller. The first precursor gas source comprises a first precursor, and the second precursor gas source comprises a second precursor. The controller is configured to control gas flow into the reaction chamber to form a layer on a substrate by means of a method as described herein.

Optionally the system further comprises one or more of a plasma gas source. The plasma gas source is arranged for providing plasma for the plasma trim.

In accordance with yet additional embodiments of the disclosure, a device or portion thereof can be formed using a method and/or a structure as described herein. The device can include a substrate, one or more insulating layers, one or more metallic layers, and one or more semiconducting layers. The device further comprises a gap filled according to a method as disclosed herein.

Further described is a field effect transistor comprising a gate contact comprising a layer formed according to a method as described herein.

Further described is a metal contact comprising a layer deposited by means of a method as described herein.

Further provided herein is a metal-insulator-metal (MIM) capacitor comprising a metal electrode comprising a layer formed by means of a method as described herein.

The illustrations presented herein are not meant to be actual views of any particular material, structure, or device, but are merely idealized representations that are used to describe embodiments of the disclosure.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

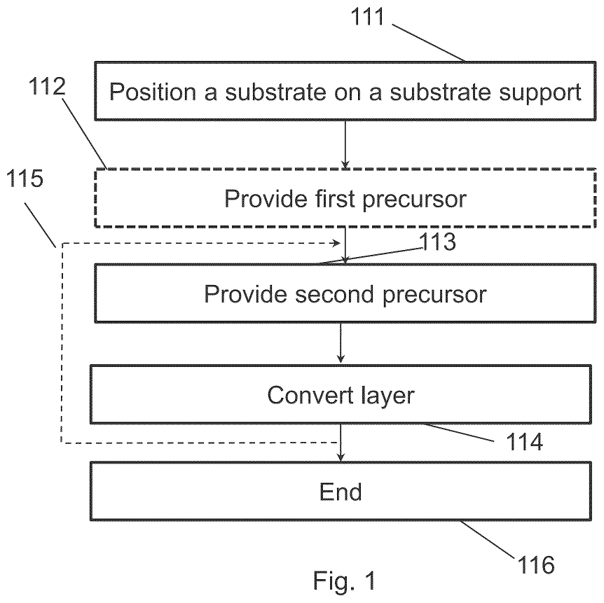

FIG. 1 shows a schematic representation of an embodiment of a method as described herein. The method can be used to fill a gap, for example, in order to form an electrode, insulator or dielectric layer in a semiconductor device. However, unless otherwise noted, the presently described methods are not limited to such applications. The method comprises a step (111) of positioning a substrate on a substrate support. The substrate support is positioned in a reaction chamber. Suitable substrate supports include pedestals, susceptors, and the like. Optionally, the method further comprises providing a first precursor into the reaction chamber in vapor phase to deposit a liner layer into the gap (112). Optionally, the reaction chamber is then purged. Purging can be done by exposing the substrate to a purge gas that, in turn, can be done, for example, by providing a purge gas to the reaction chamber. Exemplary purge gasses include noble gasses. Exemplary noble gasses include He, Ne, Ar, Xe, and Kr. Alternatively, the purging can comprise transporting the substrate through a purge gas curtain. During a purge, surplus chemicals and reaction byproducts, if any, can be removed from the substrate surface or reaction chamber, such as by purging the reaction space or by moving the substrate, before the substrate is subjected to a next step.

In some embodiments, the first precursor comprises a silicon precursor. In some embodiments, the liner layer comprises at least one material selected from the group consisting of silicon oxide, silicon, silicon carbide and silicon nitride.

Then, the method comprises providing a second precursor into the reaction chamber in vapor phase to deposit a layer into the gap (113). Optionally, the reaction chamber is then purged. In some embodiments, the layer comprises silicon or silicon nitride or silicon carbide. The layer has a first volume. The volume of the layer is defined by the thickness of the layer deposited in the gap; the length of the layer deposited in the gap, in other words the depth of the gap; and the width of the layer deposited in the gap, in other words the width of the gap. In some embodiments, the second precursor comprises a silane group. In some embodiments, the silane group is selected from the group consisting of trisilane, diiodosilane, cyclohexasilane, tetrasilane, neopentasilane, silane, disilane and cyclopentasilane.

Next, the layer is converted into a converted layer (114). The converted layer has a second volume. The second volume is greater than the first volume. In other words, the first volume of the layer expands to the second volume during the conversion step. In some embodiments, the converting step is performed by an oxidizing treatment. Any suitable oxidizing treatment can be used. In some embodiments, the oxidizing treatment comprises a treatment selected from at least one of ozone, hydrogen peroxide, oxygen plasma, oxygen radicals, ozone, water, vacuum ultraviolet ozone, vacuum ultraviolet oxygen, or steam. In some embodiments, the converting step is performed by a nitriding treatment. Any suitable nitriding treatment can be used. In some embodiments, the nitriding treatment comprises a treatment selected from at least one of ammonia, ammonia plasma, hydrazine, hydrazine plasma, nitrogen/hydrogen plasma, nitrogen plasma, or nitrogen radicals.

In some embodiments, the converted layer comprises silicon oxide. In some embodiments, the converted layer comprises silicon nitride. In some embodiments, the layer is silicon and the converted layer is silicon oxide. In some embodiments, the layer is silicon nitride and the converted layer is silicon oxide. In some embodiments, the layer is silicon carbide and the converted layer is silicon oxide. In yet some embodiments, the layer is silicon and the converted layer is silicon nitride.

Accordingly, a gap is filled, preferably without a seam. Optionally, the step of providing the second precursor (113) and the step of converting the layer (114) are repeated (115) one or more times. When the gap has be sufficiently filled seamlessly, the method ends (116).

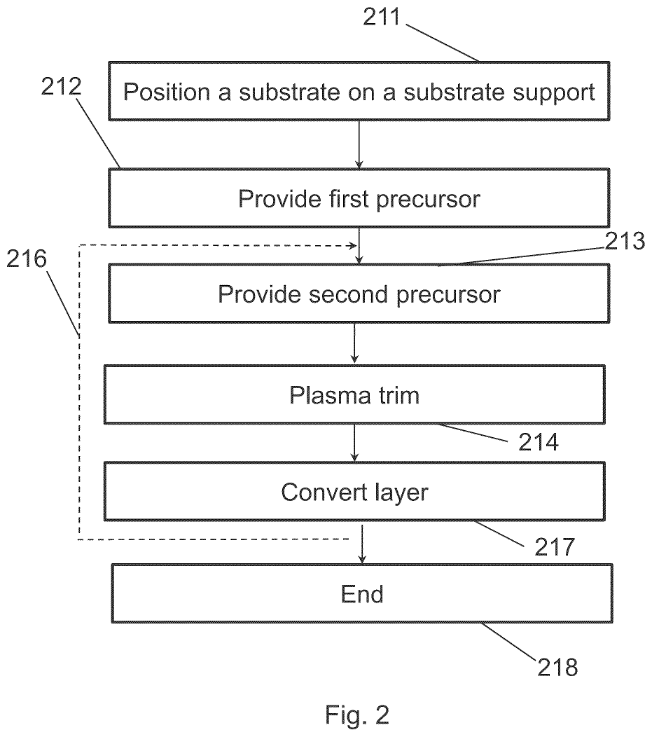

FIG. 2 schematically shows another embodiment of a method as described herein. The method of FIG. 2 is similar to that of FIG. 1 in the sense that it also comprises positioning the substrate on a substrate support (211), providing a first precursor (212), providing a second precursor (213) and converting the layer (217).

The method of FIG. 2 differs from the method of FIG. 1 in that it further comprises a step of plasma trim (214). Plasma trimming is the step in which the edges of the gap are trimmed with the help of plasma. The edges are formed into a V-shape. The aim of the plasma trim is to prevent pinch-off by removing some of the deposited film from the upper end of the gap. In other words, the plasma trim avoids the closing of the upper end of the gap and leaving a void within the gap. In some embodiments, the trim is performed with hydrogen plasma. In other words, a hydrogen gas is fed into the reaction chamber and the substrate is exposed to a direct plasma. In some embodiments, the plasma trim time is the same for each super cycle. In some embodiments, the plasma trim time is decreased in each super cycle. In some embodiments, the plasma trim is performed at a lower temperature than the deposition step (213). In some embodiments, the plasma trim is performed at a temperature of about 100° C.

In some embodiments, the plasma trim step (214) is performed in a different reaction chamber than the steps of providing the second precursor (213). Optionally, the method of FIG. 2 comprises a plurality of super cycles (216) in which the steps of providing a second precursor (213), plasma trim (214) and converting the layer (217) are repeated one or more times. After a pre-determined amount of converted material has formed on the substrate, the method of FIG. 2 ends (217).

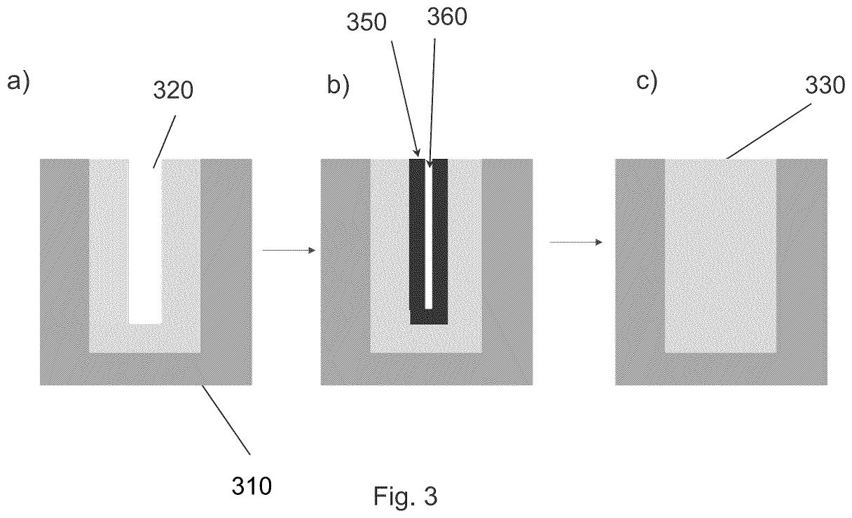

FIG. 3 illustrates the operation of a method as described herein. In particular, FIG. 3 shows a substrate (310) comprising at least one gap (320). Panel a) shows a liner layer (320) that is conformally deposited on the substrate (310). Panel b) shows the same substrate (310) with a layer (350) deposited on the substrate. The layer has a first volume. There is a seam (360) visible in the gap (320). Panel c) shows the layer that is converted into the converted layer (330). The converted layer has a second volume that is greater that the first volume which means the layer expands to fill the seam (360) in the gap (320).

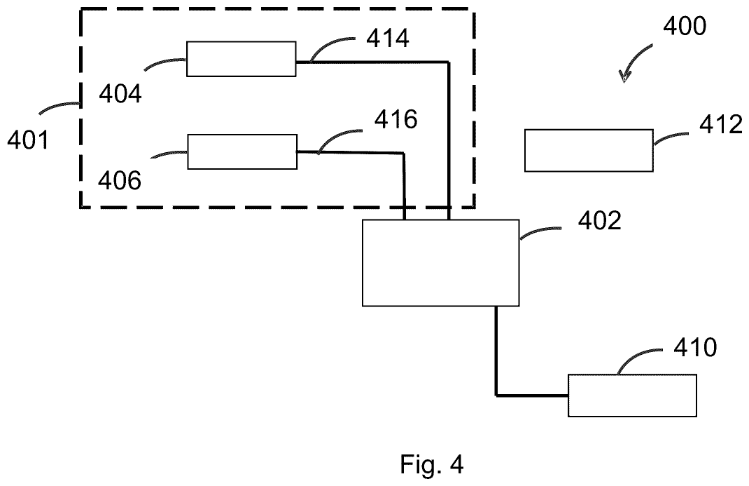

FIG. 4 illustrates a deposition assembly 400 according to the current disclosure in a schematic manner. Deposition assembly 400 can be used to perform a method as described herein and/or to form a structure or a device, or a portion thereof as described herein.

In the illustrated example, deposition assembly 400 includes one or more reaction chambers 402, a precursor injector system 401, a first precursor vessel 404, a second precursor vessel 406, an exhaust source 410, and a controller 412. The deposition assembly 400 may comprise one or more additional gas sources (not shown), such as an inert gas source, a carrier gas source and/or a purge gas source.

Reaction chamber 402 can include any suitable reaction chamber, such as an ALD or CVD reaction chamber as described herein.

The first precursor vessel 404 can include a vessel and one or more precursors as described herein—alone or mixed with one or more carrier (e.g., inert) gases. A second precursor vessel 406 can include a vessel and a second precursor as described herein—alone or mixed with one or more carrier gases. Although illustrated with two source vessels 404, 406, deposition assembly 400 can include any suitable number of source vessels. Source vessels 404, 406 can be coupled to reaction chamber 402 via lines 414, 416, which can each include flow controllers, valves, heaters, and the like. In some embodiments, the first precursor in the first precursor vessel 404 and the second precursor in the second precursor vessel 406 may be heated. In some embodiments, a vessel is heated so that a precursor or a reactant reaches a temperature between, for example, about 30° C. and about 200° C., depending on the properties of the chemical in question.

Exhaust source 410 can include one or more vacuum pumps.

Controller 412 includes electronic circuitry and software to selectively operate valves, manifolds, heaters, pumps and other components included in the deposition assembly 400. Such circuitry and components operate to introduce precursors, reactants and purge gases from the respective sources. Controller 412 can control timing of gas pulse sequences, temperature of the substrate and/or reaction chamber 402, pressure within the reaction chamber 402, and various other operations to provide proper operation of the deposition assembly 400. Controller 412 can include control software to electrically or pneumatically control valves to control flow of precursors, reactants and purge gases into and out of the reaction chamber 402. Controller 412 can include modules such as a software or hardware component, which performs certain tasks. A module may be configured to reside on the addressable storage medium of the control system and be configured to execute one or more processes.

Other configurations of deposition assembly 400 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 402. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 400, substrates, such as semiconductor wafers (not illustrated), are transferred from, e.g., a substrate handling system to reaction chamber 402. Once substrate(s) are transferred to reaction chamber 402, one or more gases from gas sources, such as precursors, reactants, carrier gases, and/or purge gases, are introduced into reaction chamber 402.

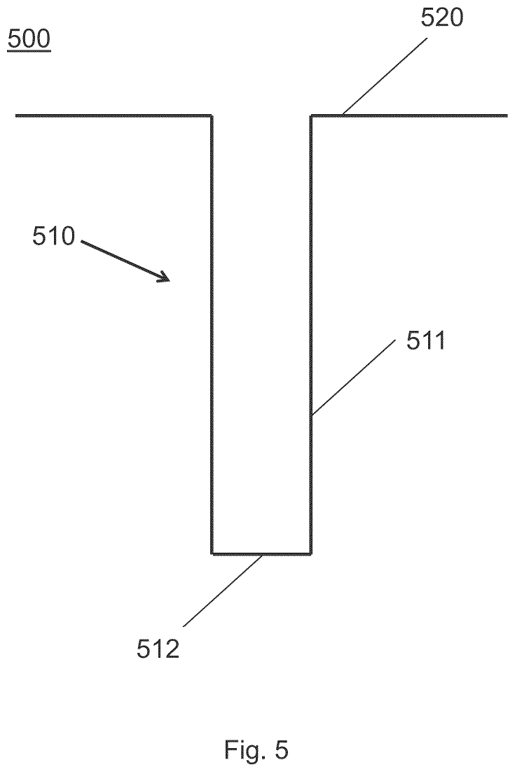

FIG. 5 shows a schematic representation of a substrate (500) comprising a gap (510). The gap (510) comprises a sidewall (511) and a distal end (512). The substrate further comprises a proximal surface (520). In some embodiments, the sidewall (511) and the distal end (512) comprise the same material. In some embodiments, at least one of the sidewall (511) and the distal end comprise a dielectric, such as a silicon containing dielectric such as silicon oxide, silicon nitride, silicon carbide, and mixtures thereof. In some embodiments, at least one of the sidewall (511) and the distal end (512) comprise a metal such as a transition metal, a post transition metal, and a rare earth metal. In some embodiments, the metal comprises Cu, Co, W, Ru, Mo, Al, or an alloy thereof.

In some embodiments, the sidewall (511) and the distal end (512) have an identical, or a substantially identical, composition. In some embodiments, the sidewall (511) and the distal end (512) have a different composition. In some embodiments, the sidewall and the distal end (512) comprise a dielectric. In some embodiments, the sidewall (511) and the distal end (512) comprise a metal. In some embodiments, the sidewall (611) comprises a metal and the distal end (512) comprises a dielectric. In some embodiments, the sidewall (511) comprises a dielectric and the distal end comprises a metal.

In some embodiments, the proximal surface (520) has the same composition as the sidewall (511). In some embodiments, the proximal surface (520) has a different composition than the sidewall (511). In some embodiments, the proximal surface (520) has a different composition than the distal end (512). In some embodiments, the proximal surface (520) has the same composition as the distal end (512).

In some embodiments, the proximal surface (520), the sidewall (511), and the distal end (512) comprise the same material. In some embodiments, the proximal surface (520), the sidewall (511), and the distal end (512) comprise a dielectric. In some embodiments, the proximal surface (520), the sidewall (511), and the distal end (512) comprise a metal. In some embodiments, the proximal surface (520), the sidewall (511), and the distal end (512) comprise a semiconductor.

1. A method for filling a gap, comprising
providing a substrate in a reaction chamber, wherein the substrate comprises at least one gap;
depositing a layer into the gap, wherein the layer has a first volume; and
converting the layer into a converted layer in the gap, wherein the converted layer has a second volume, and
wherein the second volume is greater than the first volume.

2. The method according to claim 1, further comprising a plasma trim before converting the layer into a converted layer.

3. The method according to claim 2, wherein the plasma trim is performed using a plasma gas comprising hydrogen, argon, helium or a mixture thereof.

4. The method according to claim 1, further comprising depositing a liner layer before depositing the layer into the gap.

5. The method according to claim 4, wherein the liner layer comprises at least one material selected from the group consisting of silicon oxide, silicon, silicon carbide, and silicon nitride.

6. The method according to claim 1, wherein the converting step is performed by an oxidizing treatment or a nitriding treatment.

7. The method according to claim 6, wherein the oxidizing treatment comprises a treatment selected from at least one of ozone, hydrogen peroxide, oxygen plasma, oxygen radicals, vacuum ultraviolet oxygen, or steam.

8. The method according to claim 6, wherein the nitriding treatment comprises a treatment selected from at least one of ammonia, ammonia plasma, hydrazine, hydrazine plasma, nitrogen/hydrogen plasma, nitrogen plasma, or nitrogen radicals.

9. The method according to claim 1, wherein the layer comprises silicon, silicon carbide, or silicon nitride.

10. The method according to claim 1, wherein the converted layer comprises silicon oxide or silicon nitride.

11. The method according to claim 1, wherein the layer is deposited using a first precursor.

12. The method according to claim 11, wherein the first precursor comprises a silane group.

13. The method according to claim 12, wherein silane is selected from the group consisting of tetrasilane, neopentasilane, silane, disilane trisilane, diiodosilane, cyclohexasilane and cyclopentasilane.

14. A system comprising,
a reaction chamber,
a first precursor gas source comprising a first precursor;
a second precursor gas source comprising a second precursor; and
a controller, wherein the controller is configured to control gas flow into the reaction chamber to form a converted layer in a gap on a substrate by a method according to claim 1.
